(19) United States
(12) Patent Application Publication
(10) Pub. No.: US 2011/0298811 A1
(43) Pub. Date: Dec. 8, 2011

(54) FLEXIBLE PRINTED CIRCUIT TO GLASS ASSEMBLY SYSTEM AND METHOD

(75) Inventors: Ahmad Al-Dahle, Santa Clara, CA (US); Wei H. Yao, Fremont, CA (US)

(73) Assignee: APPLE INC., Cupertino, CA (US)

(21) Appl. No.: 12/792,297

(22) Filed: Jun. 2, 2010

(51) Int. Cl. G06F 15/00; H05K 1/00; H01J 9/24; G02F 1/1345

(52) U.S. Cl. 345/501; 349/149; 174/254; 445/24

(57) ABSTRACT

Systems, methods, and devices relating to directly bonding electrode pads of a flexible printed circuit (FPC) to electrode pads of a glass substrate are provided. In one example, such a system may include a glass substrate with electrode pads and an FPC with corresponding electrode pads. A joining edge of each electrode pad of the FPC may couple directly to a joining edge of a corresponding electrode pad of the glass substrate, without an intervening conductive adhesive layer or an anisotropic conductive film (ACF) layer, or a combination thereof.

### BACKGROUND

The present disclosure relates generally to techniques for electrically and mechanically bonding a glass substrate to a flexible printed circuit (FPC) and, more particularly, to techniques for bonding a glass substrate to an FPC with reduced interconnection resistance.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

Flat panel displays, such as liquid crystal displays (LCDs) and organic light emitting diode (OLED) displays are commonly used in a wide variety of electronic devices, including such consumer electronics as televisions, computers, and handheld devices (e.g., cellular telephones, audio and video players, gaming systems, and so forth). Such display panels typically provide a flat display in a relatively thin package that is suitable for use in a variety of electronic goods. In addition, such devices typically use less power than comparable display technologies, making them suitable for use in battery-powered devices or in other contexts where it is desirable to minimize power usage.

Manufacturing such electronic displays may involve electrically and mechanically bonding a flexible printed circuit (FPC) to a glass substrate, each of which may include certain components of the display. Conventionally, an anisotropic conductive film (ACF) is placed between the FPC and glass. Conductive electrode pads on the FPC and glass may sink into the ACF when the FPC and the glass are heated and compressed. When the ACF has cured, the FPC and glass may remain both electrically and mechanically bonded to one another, but the resistance between the electrode pads of the FPC and those of the glass substrate may be relatively high. To overcome these relatively high resistances, each of the electrode pads may encompass a relatively large area.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

Embodiments of the present disclosure relate to systems, methods, and devices relating to directly bonding electrode pads of a flexible printed circuit (FPC) to electrode pads of a glass substrate. In one example, such a system may include a glass substrate with electrode pads and an FPC with corresponding electrode pads. A joining edge of each electrode pad of the FPC may couple directly to a joining edge of a corresponding electrode pad of the glass substrate, without an intervening conductive adhesive layer or an anisotropic conductive film (ACF) layer, or a combination thereof.

### BRIEF DESCRIPTION OF THE DRAWINGS

Various aspects of this disclosure may be better understood upon reading the following detailed description and upon reference to the drawings in which:

FIG. 1 is a block diagram of components of an electronic device, in accordance with an embodiment;

FIG. 2 is a front view of a handheld electronic device, in accordance with an embodiment;

FIG. 3 is a perspective view of a notebook computer, in accordance with an embodiment;

FIG. 4 is a circuit diagram illustrating the structure of unit pixels of a display of the device of FIG. 1, in accordance with an embodiment;

FIG. 5 is a schematic diagram of a process for bonding a flexible printed circuit (FPC) to a glass substrate of the display of the device of FIG. 1, in accordance with an embodiment;

FIGS. 6-10 are schematic diagrams of embodiments for performing the bonding process of FIG. 5;

FIG. 11 is a flowchart describing an embodiment of a method for performing the bonding process of FIG. 5; and

FIG. 12 is a schematic diagram of an embodiment of a flexible printed circuit (FPC) bonded to a glass substrate according to the techniques disclosed herein.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Present embodiments relate to bonding a flexible printed circuit (FPC) to a glass substrate, as may be undertaken during the manufacture of an electronic display or a device incorporating an electronic display. In particular, rather than bonding the FPC to the glass substrate using an anisotropic conductive film (ACF), which may result in a relatively high resistance between electrodes of the FPC and the glass substrate, techniques disclosed herein may involve directly coupling the FPC to the glass substrate. The FPC may include electrode pads that correspond to respective electrode pads on the glass substrate. To bond the FPC to the glass substrate, an adhesive paste may be placed between the pads of the FPC or the glass substrate, and the pads of the FPC may be compressed directly (i.e., without an intervening ACF layer) into the corresponding pads of the glass substrate.

The corresponding electrode pads may adhere to one another at least in part because of their shape and/or composition. For example, in certain embodiments, at least some electrode pads may be coated with a deformable conductor, such as gold or copper, which may deform when compressed or heated and adhere to corresponding electrode pads on the other of the glass substrate or FPC. In some embodiments, the electrode pads may have a convex or rough pattern etched onto joining edges (e.g., points at which the electrode pads of the FPC contact corresponding electrode pads of the glass substrate). Additionally or alternatively, corresponding electrode pads may have relatively interlocking patterns etched onto such points of contact.

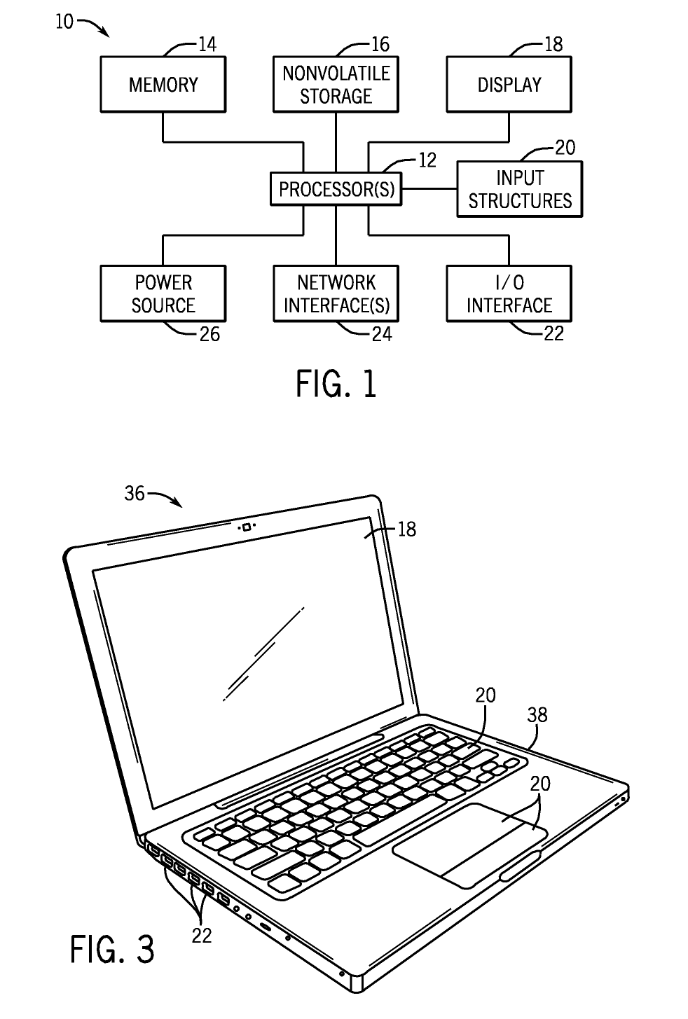

With the foregoing in mind, FIG. 1 represents a block diagram of an electronic device 10 employing components having a flexible printed circuit (FPC) bonded directly to a glass substrate. Among other things, the electronic device 10 may include processor(s) 12, memory 14, nonvolatile storage 16, a display 18, input structures 20, an input/output (I/O) interface 22, network interface(s) 24, and/or a power source 26. In alternative embodiments, the electronic device 10 may include more or fewer components.

In general, the processor(s) 12 may govern the operation of the electronic device 10. In some embodiments, based on instructions loaded into the memory 14 from the nonvolatile storage 16, the processor(s) 12 may respond to user touch gestures input via the display 18. In addition to these instructions, the nonvolatile storage 16 also may store a variety of data. By way of example, the nonvolatile storage 16 may include a hard disk drive and/or solid state storage, such as Flash memory.

The display 18 may be a flat panel display, such as a liquid crystal display (LCD) or an organic light emitting diode (OLED) display. As discussed in greater detail below, certain flexible printed circuit (FPC) and glass substrate components of the display 18 may be bonded to one another in a direct manner rather than via an anisotropic conductive film (ACF). As a result, the resistance between the FPC and the glass may be lower, and electrical signals sent to control the display 18 may be of lower power and/or certain electrode pads connecting the FPC and glass substrate may encompass less area.

The display 18 also may represent one of the input structures 20. Other input structures 20 may include, for example, keys, buttons, and/or switches. The I/O ports 22 of the electronic device 10 may enable the electronic device 10 to transmit data to and receive data from other electronic devices 10 and/or various peripheral devices, such as external keyboards or mice. The network interface(s) 24 may enable personal area network (PAN) integration (e.g., Bluetooth), local area network (LAN) integration (e.g., Wi-Fi), and/or wide area network (WAN) integration (e.g., 3G). The power source 26 of the electronic device 10 may be any suitable source of power, such as a rechargeable lithium polymer (Li-poly) battery and/or alternating current (AC) power converter. By employing the presently-disclosed techniques, the electronic device 10 may reduce the amount of power consumed from the power source 26.

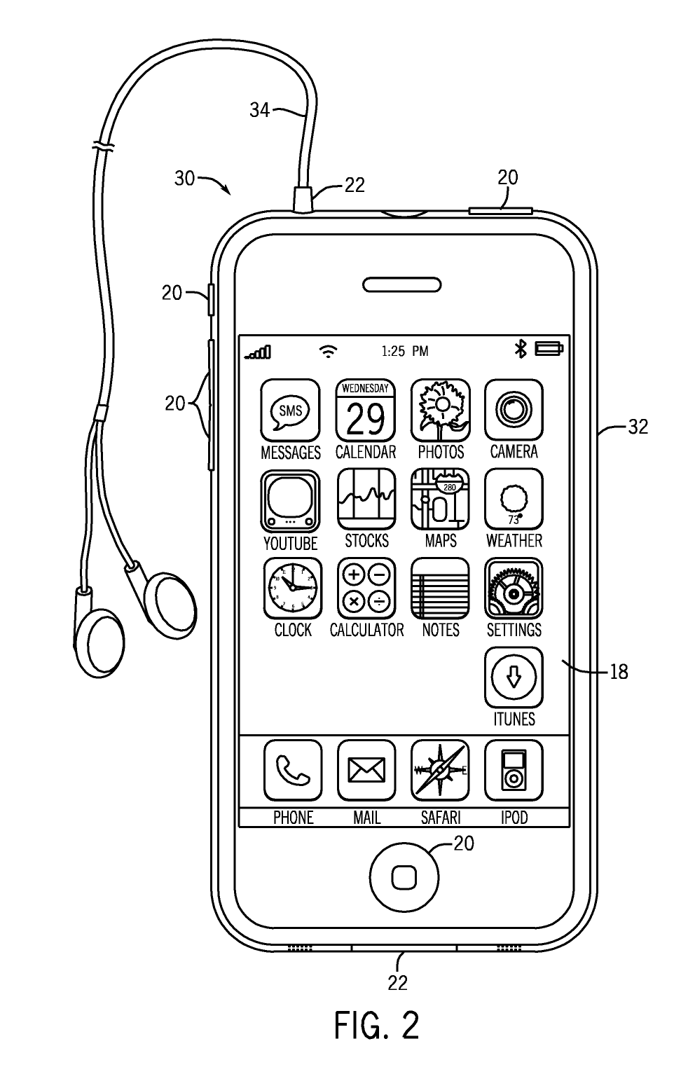

FIG. 2 illustrates an electronic device 10 in the form of a handheld device 30, here a cellular telephone. It should be noted that while the handheld device 30 is provided in the context of a cellular telephone, other types of handheld devices (such as media players for playing music and/or video, personal data organizers, handheld game platforms, and/or combinations of such devices) may also be suitably provided as the electronic device 10. Further, the handheld device 30 may incorporate the functionality of one or more types of devices, such as a media player, a cellular phone, a gaming platform, a personal data organizer, and so forth.

For example, in the depicted embodiment, the handheld device 30 is in the form of a cellular telephone that may provide various additional functionalities (such as the ability to take pictures, record audio and/or video, listen to music, play games, and so forth). As discussed with respect to the general electronic device of FIG. 1, the handheld device 30 may allow a user to connect to and communicate through the Internet or through other networks, such as local or wide area networks. The handheld device 30 also may communicate with other devices using short-range connections, such as Bluetooth and near field communication (NFC). By way of example, the handheld device 30 may be a model of an iPod® or iPhone® available from Apple Inc. of Cupertino, Calif.

The handheld device 30 may include an enclosure 32 or body that protects the interior components from physical damage and shields them from electromagnetic interference. The enclosure 32 may be formed from any suitable material, such as plastic, metal or a composite material, and may allow certain frequencies of electromagnetic radiation to pass through to wireless communication circuitry within handheld device 30 to facilitate wireless communication. The enclosure 32 may also include user input structures 20 through which a user may interface with the device. Each user input structure 20 may be configured to help control a device function when actuated. For example, in a cellular telephone implementation, one or more input structures 20 may be configured to invoke a “home” screen or menu to be displayed, to toggle between a sleep and a wake mode, to silence a ringer for a cell phone application, to increase or decrease a volume output, and so forth.

The display 18 may display a graphical user interface (GUI) that allows a user to interact with the handheld device 30. Icons of the GUI may be selected via a touch screen included in the display 18, or may be selected by one or more input structures 20, such as a wheel or button. The handheld device 30 also may include various I/O ports 22 that allow connection of the handheld device 30 to external devices. For example, one I/O port 22 may be a port that allows the transmission and reception of data or commands between the handheld device 30 and another electronic device, such as a computer. Such an I/O port 22 may be a proprietary port from Apple Inc. or may be an open standard I/O port. Another I/O port 22 may include a headphone jack to allow a headset 34 to connect to the handheld device 30.

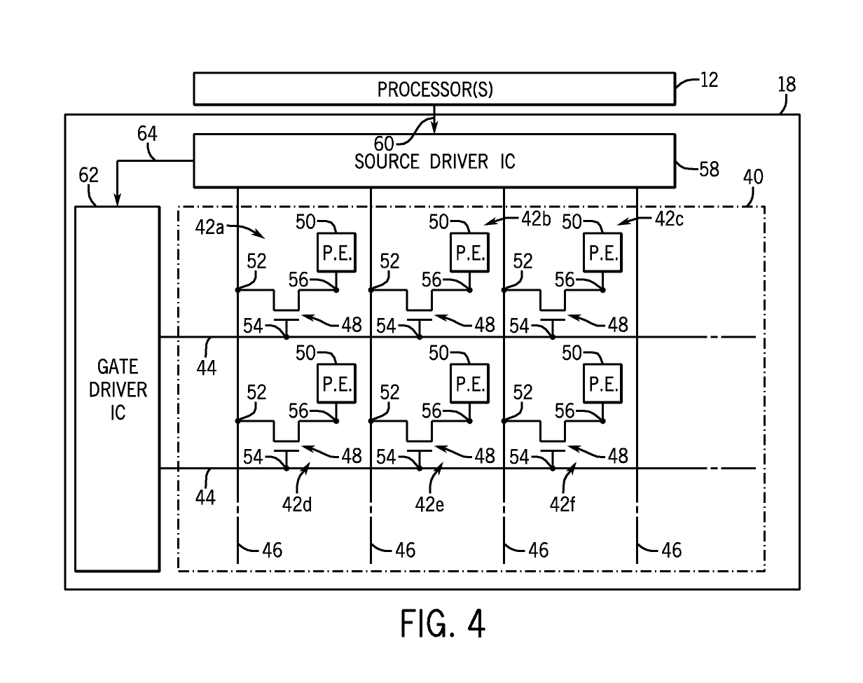

In addition to the handheld device 30 of FIG. 2, the electronic device 10 may also take the form of a computer or other type of electronic device. Such a computer may include a computer that is generally portable (such as a laptop, notebook, and/or tablet computer) and/or a computer that is generally used in one place (such as a conventional desktop computer, workstation and/or servers). In certain embodiments, the electronic device 10 in the form of a computer may be a model of a MacBook®, MacBook® Pro, MacBook Air®, iMac®, Mac® mini, or Mac Pro® available from Apple Inc. In another embodiment, the electronic device 10 may be a tablet computing device, such as an iPad® available from Apple Inc. By way of example, a laptop computer 36 is illustrated in FIG. 3 and represents an embodiment of the electronic device 10 in accordance with one embodiment of the present disclosure. Among other things, the computer 36 includes a housing 38, a display 18, input structures 20, and I/O ports 22.

In one embodiment, the input structures 22 (such as a keyboard and/or touchpad) may enable interaction with the computer 36, such as to start, control, or operate a GUI or applications running on the computer 36. For example, a keyboard and/or touchpad may allow a user to navigate a user interface or application interface displayed on the display 18. Also as depicted, the computer 36 may also include various I/O ports 22 to allow connection of additional devices. For example, the computer 36 may include one or more I/O ports 22, such as a USB port or other port, suitable for connecting to another electronic device, a projector, a supplemental display, and so forth. In addition, the computer 36 may include network connectivity, memory, and storage capabilities, as described with respect to FIG. 1.

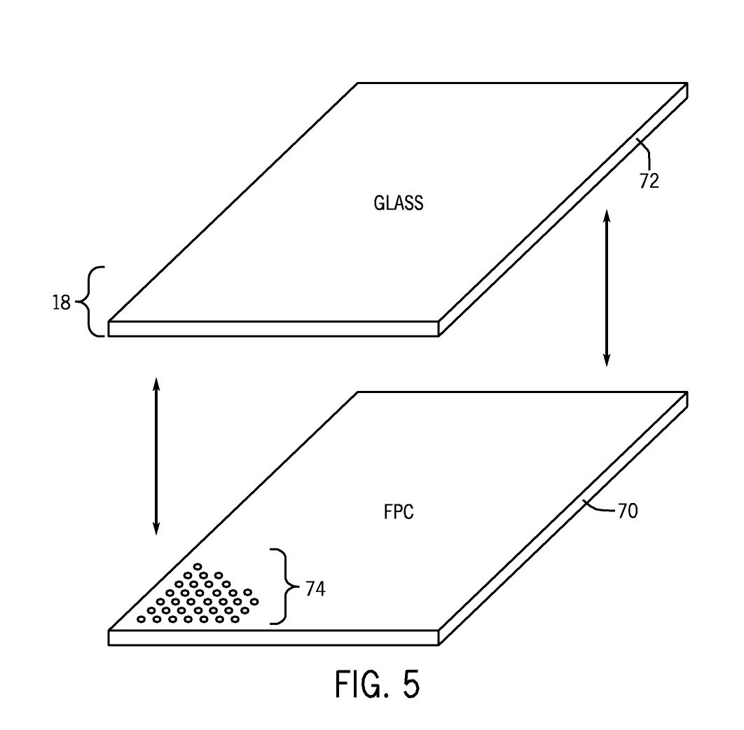

As noted briefly above, the display 18 represented in the embodiments of FIGS. 1-3 may be a liquid crystal display (LCD). FIG. 4 represents a circuit diagram of such a display 18, in accordance with an embodiment. As shown, the display 18 may include an LCD display panel 40 including unit pixels 42 disposed in a pixel array or matrix. In such an array, each unit pixel 42 may be defined by the intersection of rows and columns, represented here by the illustrated gate lines 44 (also referred to as “scanning lines”) and source lines 46 (also referred to as “data lines”), respectively. Although only six unit pixels, referred to individually by the reference numbers 42a-42f, respectively, are shown for purposes of simplicity, it should be understood that in an actual implementation, each source line 46 and gate line 44 may include hundreds or thousands of such unit pixels 42.

As shown in the present embodiment, each unit pixel 42 includes a thin film transistor (TFT) 48 for switching a respective pixel electrode 50. A source 52 of each TFT 48 may be electrically connected to a source line 46, and a gate 54 of each TFT 48 may be electrically connected to a gate line 44. A drain 56 of each TFT 48 may be electrically connected to a respective pixel electrode 50. Each TFT 48 serves as a switching element which may be activated and deactivated (e.g., turned on and off) for a predetermined period based upon the respective presence or absence of a scanning signal at the gate 54 of the TFT 48. When activated, the TFT 48 may pass an image signal from the source line 46 to the pixel electrode 50. A source driver integrated circuit (IC) 58, which may include a chip, such as a processor or ASIC, may be integrated into the display panel 40 or may be apart, as illustrated. The source driver IC 58 may receive image data 60 from the processor(s) 12 and/or a display controller and send corresponding image signals to the unit pixels 42 of the panel 40.

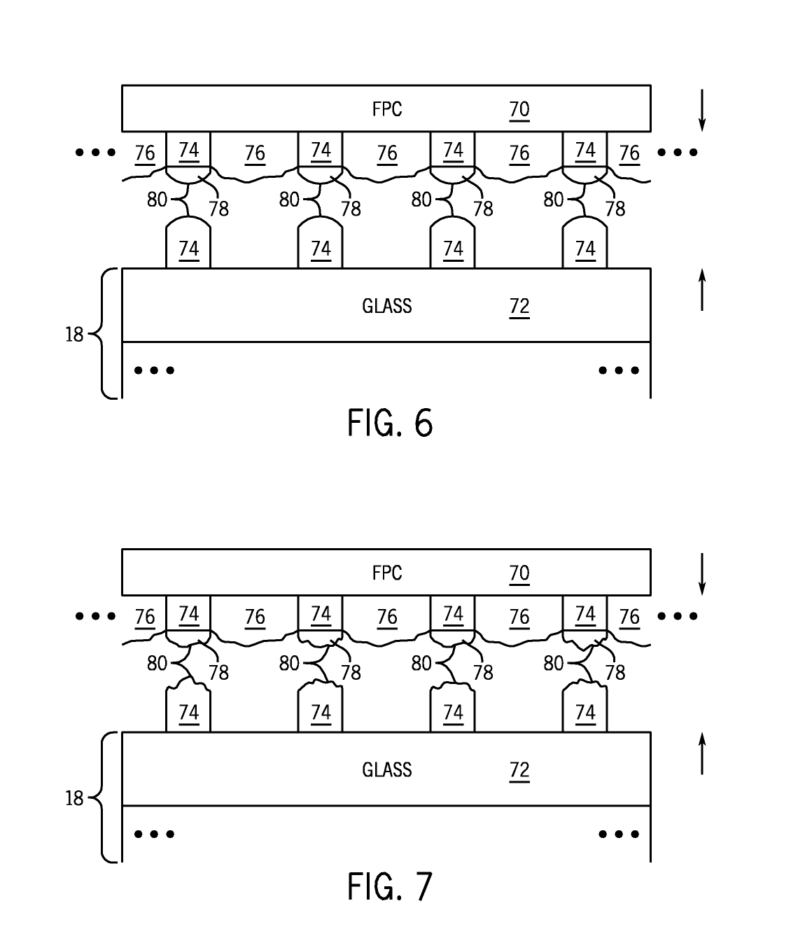

In operation, the source driver IC 58 receives image data 60 from the processor(s) 12 or a separate display controller. The image data 60 may pass from the processor(s) 12 and/or a display controller to the source driver IC 58 by way of a flexible printed circuit (FPC) 70, which may be electrically and mechanically bonded to a glass substrate 72 of the display 18, as illustrated in FIG. 5. More specifically, a series of electrode pads 74 on the FPC 70 may couple to a corresponding series of electrode pads 74 on the glass substrate 72 (not visible in FIG. 5). The electrode pads 74 of the glass substrate 72 may carry the image data 60 signal from the electrodes 74 of the FPC 70 to the source driver IC 58, which may be disposed within or beyond the glass substrate 72. In alternative embodiments, the source driver IC 58 and/or gate driver IC 62 may be located outside of the display panel 40. For such embodiments, the FPC 70 may transmit pixel 42 data signals and individual row activation signals from the source driver IC 58 and/or gate driver IC 62 to the display panel 40 via the electrode pads 74.

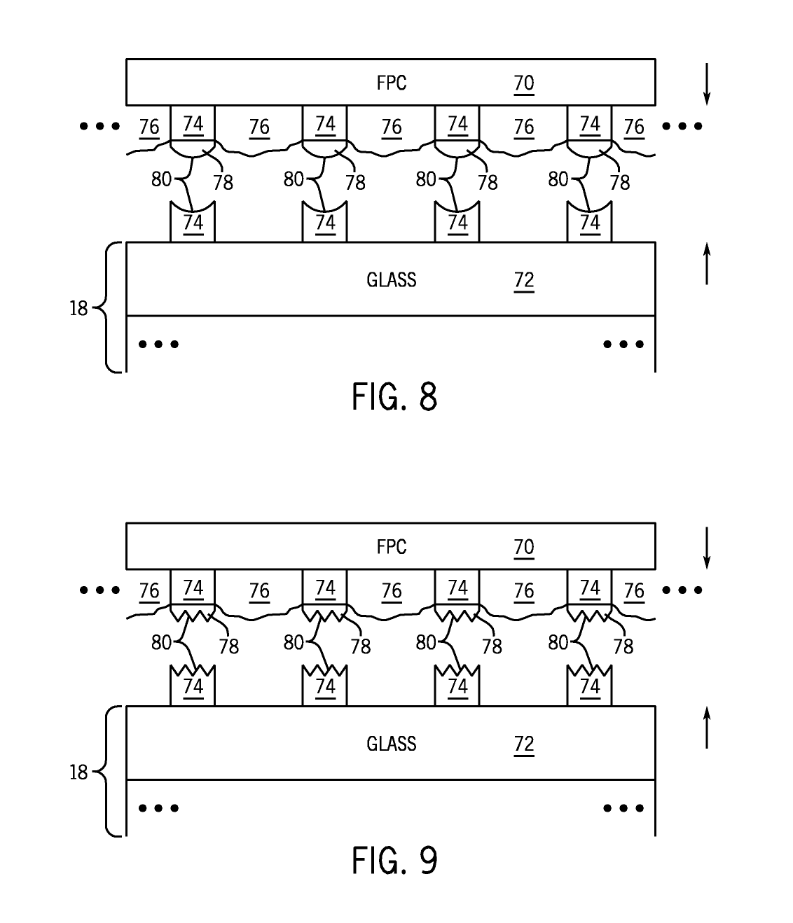

The corresponding electrode pads 74 of the FPC 70 and the glass substrate 72 may bond to one another without an intervening layer of anisotropic conductive film (ACF). Accordingly, in some embodiments, the electrode pads 74 may have a smaller area than conventional electrode pads, since a lower resistance may exist between the various electrode pads 74. The electrode pads 74 may take a variety of shapes and/or compositions to bond to one another. FIGS. 6-10 present various configurations of the electrode pads 74 to enable the electrode pads 74 to bond directly to one another without an intervening layer of anisotropic conductive film (ACF). The embodiments presented in FIGS. 6-10 are intended to be examples and are not exhaustive. Thus, it should be understood that the electrode pads 74 may take any suitable configuration to assist in bonding to one another, including those illustrated in FIGS. 6-10.

In each of the embodiments of FIGS. 6-10, an adhesive 76 may be “silk screened” or otherwise placed onto the FPC 70 between the electrode pads 74 of the FPC 70. In alternative embodiments, the adhesive 76 may be placed between the electrode pads 74 of the glass substrate 72 instead of the FPC 70, or may be placed between both the electrode pads 74 of the FPC 70 and the electrode pads 74 of the glass substrate 72. The adhesive 76 may be substantially nonconductive or highly resistive, and may provide support for the direct bonding of corresponding electrode pads 74 without shunting the image data 60 signals to other electrode pads 74.

Additionally, in each of the embodiments discussed below, each electrode pad 74 of the FPC 70 may correspond to a respective electrode pad 74 of the glass substrate 72. The electrode pads 74 may represent solid conductors or a nonconductive material that has been plated with a conductive material. Further, at least one electrode pad 74 of each pair of corresponding electrode pads 74 generally may be plated with a deformable conductor 78, which may be a malleable conductive material such as gold or copper. When the FPC 70 and the glass substrate 72 are compressed into one another, the deformable conductor 78 may deform to bond the pairs of corresponding electrode pads 74 electrically and mechanically to one another. Also, it should be understood that the electrode pads 74 of FIGS. 6-10 are illustrated schematically and are not necessarily shown to scale. For example, the electrode pads 74 may be relatively wider or thinner, or taller or shorter than illustrated.

In some embodiments, the electrode pads 74 of the FPC 70 and of the glass substrate 72 may have a generally convex shape. As illustrated in FIG. 6, the electrode pads 74 of the FPC 70 may include deformable conductors 78 at joining edges 80 (e.g., locations at which the corresponding pairs of electrode pads 74 will bond when the FPC 70 and the glass substrate 72 are compressed together). Additionally or alternatively, the deformable conductors 78 may be located on the joining edges 80 of the electrode pads 74 of the glass substrate 72.

In FIG. 6, the joining edges 80 of the electrode pads 74 of the FPC 70 and of the glass substrate 72 generally form a convex shape. Thus, when the electrode pads 74 are compressed into one another, the deformable conductor 78 on the joining edge 80 of one electrode pad 74 is likely to deform around the convex joining edge 80 of a corresponding electrode pad 74, bonding the two electrode pads 74 together. To the extent that the deformable conductor 78, when compressed between the two electrode pads 74, does not form a sufficiently tight bond between the electrode pads 74, the adhesive 76 may provide additional bonding support by adhering the FPC 70 to the glass substrate 72.

The joining edges 80 of the electrode pads 74 may have a relatively “rough” shape to enhance bonding in certain embodiments. For example, as illustrated in FIG. 7, the joining edges 80 of corresponding pairs of electrode pads 74 may be slightly jagged or rough. Thus, when the joining edges 80 are compressed into one another, the two joining edges 80 may be likely to meet one another in at least several locations. When certain of the electrode pads 74 include the deformable conductor 78, the deformable conductor 78 also may have a rough or slightly jagged shape.

In some embodiments, corresponding pairs of electrode pads 74 may be somewhat interlocking For example, as shown in FIG. 8, the joining edges of the electrode pads 74 of the flexible printed circuit (FPC) 70 may be convex, while the joining edges 80 of the electrode pads 74 of the glass substrate 72 may be concave. In the presently illustrated embodiment, the convex joining edges 80 are formed from the deformable conductor 78.

To reduce the likelihood of a mismatch between the pairs of electrode pads 74, the joining edges 80 of the pairs of electrode pads 74 shown in FIG. 8 may not be perfectly interlocking Rather, the convex joining edges 80 may be more convex than the concave joining edges 80 are concave. Thus, when the joining edges 80 of the corresponding pairs of electrode pads 74 are compressed together, the deformable conductors 78 of the convex joining edges 80 may deform to match the slightly concave joining edges 80 of the corresponding electrode pads 74.

In another embodiment involving interlocking joining edges 80, illustrated by FIG. 9, the joining edges 80 of the electrode pads 74 of both the FPC 70 and the glass substrate 72 may be more substantially interlocking than the embodiment of FIG. 8. In the embodiment of FIG. 9, respectively interlocking joining edges 80 may be very jagged, but in other embodiments, the interlocking joining edges 80 may take other respectively interlocking shapes (e.g., respectively interlocking rectangles or curves). One advantage presented by such highly interlocking joining edges 80 may include an increased likelihood of alignment between the two electrode pads 74 in each corresponding pair of electrode pads 74. That is, if the alignment is slightly to the left or to the right when the FPC 70 and the glass substrate 72 are compressed together, the interlocking shape of the joining edges 80 may cause the alignment to improve before the respective electrode pads 74 have bonded to one another.

Joining edges 80 of the corresponding pairs of electrode pads 74 also may vary in shape and/or composition, as illustrated in FIG. 10. For such embodiments, the joining edge 80 of one of the two corresponding electrode pads 74 may be of a relatively smooth shape and may include the deformable conductor 78. The joining edge 80 of the other of the two corresponding electrode pads 74 may have a relatively rough or jagged shape. When the flexible printed circuit (FPC) 70 is compressed toward the glass substrate 72, the rough joining edges 80 may “bite” into the corresponding smooth joining edges 80 to electrically and mechanically bond the FPC 70 to the glass substrate 72.

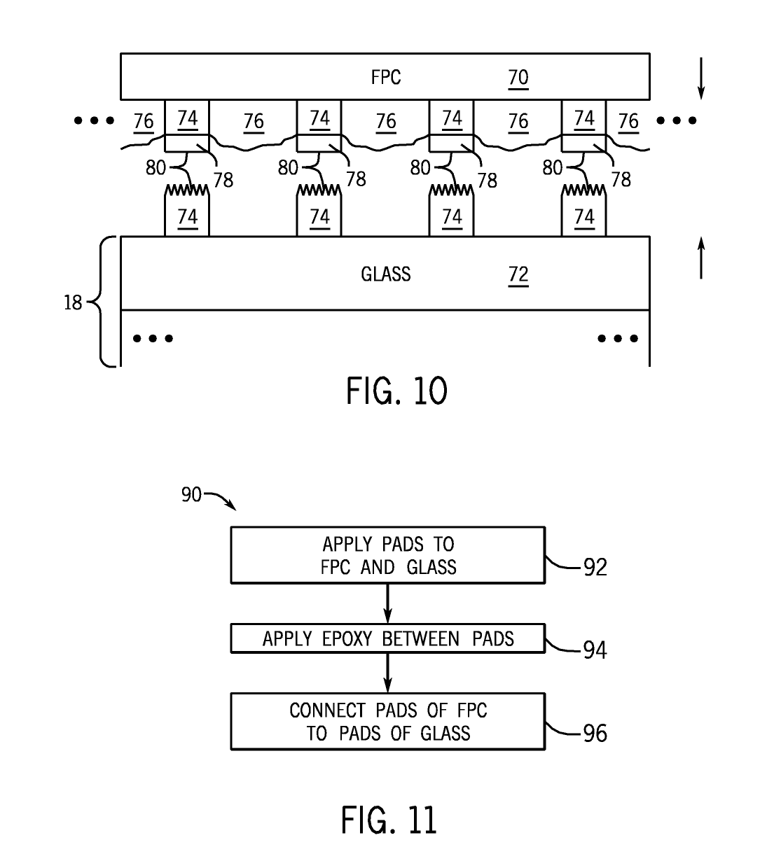

FIG. 11 represents a flowchart 90 describing an embodiment for bonding the flexible printed circuit (FPC) 70 to the glass substrate 72. The flowchart 90 may begin when the electrode pads 74 are applied to the FPC 70 and the glass substrate 72 (block 92). The application of the electrode pads 74 may occur when the display 18 (and thus the glass substrate 72 of the display 18) or the FPC 70 are manufactured, or may take place at a later time. The application of the electrode pads 74 may involve etching and/or plating the electrode pads 74 onto specific sites on the FPC 70 and the glass substrate 72, and/or shaping the joining edges 80 of the electrode pads 74 to assist with bonding. In some embodiments, a deformable conductor 78 formed from a malleable conductive material also may be plated onto the joining edges 80 of one or more of the electrode pads 74.

Before joining the FPC 70 and the glass substrate 72, the adhesive 76 may be screened or otherwise placed between the electrode pads 74 of the FPC 70, the glass substrate 72, or both (block 94). Thereafter, the FPC 70 and the glass substrate 72 may be compressed together such that the electrode pads 74 of the FPC 70 generally align with those of the glass substrate 72 (block 96). In some embodiments, heat also may be applied. The compression and/or heat may cause the electrode pads 74 to bond to one another. In particular, the compression and/or heat may cause the deformable conductor 78 of one electrode pad 74 to deform and/or melt onto the corresponding electrode pad 74, thereby forming an electrical and mechanical bond.

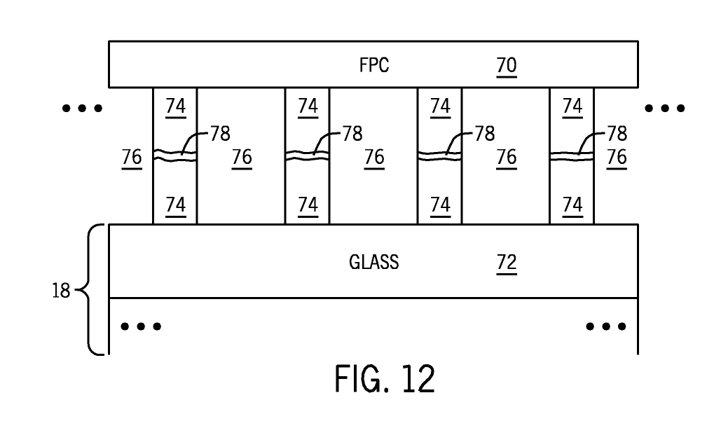

The flexible printed circuit (FPC) 70 then may have bonded to the glass substrate 72 directly via the electrode pads 74, without an intervening anisotropic conductive film (ACF) layer, as illustrated by FIG. 12. As shown, corresponding pairs of electrode pads 74 may effectively form a single electrode from the FPC 70 to the glass substrate 72, surrounded by the adhesive 76. Since the electrode pads 74 are directly connected to one another, the resistance may be relatively low. Accordingly, the area of the electrode pads 74 may be reduced from conventional sizes and/or the image data 60 signals sent across the electrode pads 74 may be of lower power.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

What is claimed is:

1. A system comprising:
a glass substrate having disposed thereon a first plurality of electrode pads; and
a flexible printed circuit having disposed thereon a second plurality of electrode pads, wherein a joining edge of each electrode pad of the second plurality of electrode pads is configured to couple directly to a joining edge of a corresponding electrode pad of the first plurality of electrode pads without an intervening conductive adhesive layer or an anisotropic conductive film layer, or a combination thereof.

2. The system of claim 1, wherein one or more electrode pads of the first plurality of electrode pads or the second plurality of electrode pads, or a combination thereof, comprise a deformable conductive material.

3. The system of claim 2, wherein the deformable conductive material comprises a malleable metal plated over the joining edge of each of the one or more electrode pads.

4. The system of claim 2, wherein the deformable conductive material is configured such that, when the one or more electrode pads are coupled to corresponding electrode pads, the deformable conductive material deforms to connect the joining edges of the one or more electrode pads and the corresponding electrode pads.

5. The system of claim 2, wherein the deformable conductive material comprises gold or copper, or a combination thereof.

6. The system of claim 1, wherein the joining edge of at least one of the first plurality of electrode pads or the second plurality of electrode pads, or a combination thereof, comprises a convex shape.

7. The system of claim 1, wherein the joining edge of at least one of the first plurality of electrode pads or the second plurality of electrode pads, or a combination thereof, comprises a rough or jagged shape.

8. The system of claim 1, wherein the joining edges of two or more corresponding electrode pads of the first plurality of electrode pads and the second plurality of electrode pads comprise an interlocking shape.

9. The system of claim 1, wherein the joining edge of each electrode pad of the second plurality of electrode pads is configured to couple directly to the joining edge of the corresponding electrode pad of the first plurality of electrode pads following the application of heat or pressure, or a combination thereof.

10. A method comprising:
providing a glass substrate having a first plurality of electrode pads;
providing a flexible printed circuit having a second plurality of electrode pads, wherein the first plurality of electrode pads corresponds respectively to the second plurality of electrode pads; and
compressing the first plurality of electrode pads directly against the second plurality of electrode pads such that the glass substrate and the flexible printed circuit are electrically and mechanically bonded.

11. The method of claim 10, wherein heat is applied while the first plurality of electrode pads is compressed directly against the second plurality of electrode pads.

12. The method of claim 10, wherein the first plurality of electrode pads or the second plurality of electrode pads, or a combination thereof, comprises a malleable conductor and wherein the first plurality of electrode pads is compressed directly against the second plurality of electrode pads such that the malleable conductor deforms to bond corresponding electrode pads of the first plurality of electrode pads and the second plurality of electrode pads.

13. The method of claim 10, comprising providing an adhesive between the first plurality of electrode pads of the glass substrate or between the second plurality of the electrode pads of the flexible printed circuit, or a combination thereof, so that the adhesive bonds the flexible printed circuit to the glass substrate.

14. The method of claim 13, wherein the adhesive is substantially nonconductive.

15. A display device comprising:
a glass substrate housing liquid crystal display circuitry, wherein an outer edge of the glass substrate has a first plurality of electrode pads and wherein the first plurality of electrode pads is electrically connected to the liquid crystal display circuitry; and
a flexible printed circuit configured to provide display signals to the liquid crystal display circuitry via a second plurality of electrode pads disposed on the flexible printed circuit, wherein the second plurality of electrode pads is bonded directly to the first plurality of electrode pads without an intervening layer of conductive or anisotropic conductive material, or any combination thereof.

16. The display device of claim 15, wherein the first plurality of electrode pads or the second plurality of electrode pads, or both, comprise substantially interlocking edges at points where the first plurality of electrode pads and the second plurality of electrode pads are bonded directly to one another.

17. The display device of claim 15, wherein the first plurality of electrode pads and the second plurality of electrode pads comprise different shaped edges at points where the first plurality of electrode pads and the second plurality of electrode pads are bonded directly to one another.

18. The display device of claim 15, wherein the first plurality of electrode pads and the second plurality of electrode pads are bonded directly to one another via a malleable conductive material.

19. The display device of claim 18, wherein the malleable conductive material is plated onto the first plurality of electrode pads or the second plurality of electrode pads, or both.

20. The display device of claim 15, wherein the second plurality of electrode pads is bonded directly to the first plurality of electrode pads at least in part via a substantially nonconductive epoxy disposed between the first plurality of electrodes and between the second plurality of electrodes.

21. A system comprising:
a processor configured to generate display signals;
a display having display circuitry configured to display visual information based on the display signals, wherein the display includes a first plurality of electrodes that is electrically connected to the display circuitry; and
a flexible printed circuit configured to provide the display signals to the display via a second plurality of electrodes that corresponds respectively to the first plurality of electrodes, wherein the second plurality of electrodes and the first plurality of electrodes are bonded directly to one another without an intervening conductive adhesive layer or an anisotropic conductive film layer, or a combination thereof.

22. The system of claim 21, wherein one or more of the first plurality of electrode pads or the second plurality of electrode pads, or both, comprise a deformable conductor configured to deform when heat or pressure, or a combination thereof, is applied to the conductor.

23. The system of claim 22, wherein the deformable conductor comprises a malleable metal.
